(19) United States
(12) Patent Application Publication
(10) Pub. No.: US 2012/0052788 A1
(43) Pub. Date: Mar. 1, 2012

(54) AIR FLOW CABINET

(76) Inventors: Michael Mallia, Northport, NY (US); Paul Mallia, East Setauket, NY (US)

(21) Appl. No.: 13/216,649

(22) Filed: Aug. 24, 2011

Related U.S. Application Data
(60) Provisional application No. 61/377,318, filed on Aug. 26, 2010.

(51) Int. Cl. F24F 7/007; H05K 5/02; A47B 81/00; F24F 13/08; A47B 96/00

(52) U.S. Cl. 454/289; 454/284; 454/329; 312/352; 312/236; 312/223.1

(57) ABSTRACT

A cabinet comprising a first baffle disposed so that a device may be mounted in the cabinet below the first baffle. The first baffle further disposed so as to prevent air in a front of the cabinet below the first baffle from mixing with air above the first baffle. A second baffle is disposed so as to prevent air in the first side of the cabinet below the second baffle from mixing with air in the first side of the cabinet above the second baffle. A third baffle is disposed so as to prevent air in the first side of the cabinet in front of the third baffle from mixing with air in a rear of the cabinet. A fourth baffle is disposed so as to prevent air below the device and toward a front of the fourth baffle from mixing with air in a rear of the cabinet.

### CROSS-REFERENCE TO RELATED APPLICATIONS

This application claims priority to provisional application 61/377,318 filed Aug. 26, 2010, the entirety of which is hereby incorporated by reference.

### BACKGROUND OF THE INVENTION

1. Field of the Invention

This disclosure relates to an air flow cabinet and, more particularly, to an air flow cabinet capable of reducing an average temperature of air inside the cabinet when a device is operating inside the cabinet.

2. Description of the Related Art

Electronic devices such as switches and routers generate heat while in operation. If the electronic devices become too hot, operating performance may be affected. Air flow cabinets may be used to reduce an average temperature of the air inside the cabinet and proximate to the electronic devices. This disclosure describes an improvement over these prior art systems.

### SUMMARY OF THE INVENTION

One embodiment of the invention is a cabinet effective to mount a device. The cabinet may comprise a front, a rear, a first side, a second side, a top, and a bottom. A first baffle may be disposed in the cabinet so that the device may be mounted in the cabinet below the first baffle, the first baffle further disposed in the cabinet so as to prevent air in a front of the cabinet below the first baffle from mixing with air above the first baffle. A second baffle may be disposed in the first side, the second baffle disposed in the cabinet so as to prevent air in the first side of the cabinet below the second baffle from mixing with air in the first side of the cabinet above the second baffle. A third baffle may be disposed in the first side, the third baffle disposed in the cabinet so as to prevent air in the first side of the cabinet in front of the third baffle from mixing with air in a rear of the cabinet. A fourth baffle may be disposed in the rear of the cabinet, the fourth baffle disposed in the cabinet so as to prevent air beneath the device and toward a front of the fourth baffle from mixing with air in a rear of the cabinet.

Another embodiment of the invention is a combination of a cabinet and a device. The combination may comprise a cabinet and a device mounted in the cabinet. The cabinet may comprise a front, a rear, a first side, a second side, a top, and a bottom. A first baffle may be disposed above the device, the first baffle further disposed in the cabinet so as to prevent air in a front of the cabinet below the first baffle from mixing with air above the first baffle. A second baffle may be disposed in the first side, the second baffle disposed in the cabinet so as to prevent air in the first side of the cabinet below the second baffle from mixing with air in the first side of the cabinet above the second baffle. A third baffle may be disposed in the first side, the third baffle disposed in the cabinet so as to prevent air in the first side of the cabinet in front of the third baffle from mixing with air in a rear of the cabinet. A fourth baffle may be disposed in the rear of the cabinet, the fourth baffle disposed in the cabinet so as to prevent air below the device and in a front of the fourth baffle from mixing with air in a rear of the cabinet.

Yet another embodiment of the invention is a method for reducing a temperature in a cabinet. The method may comprise preventing air in a front of the cabinet below a first baffle from mixing with air above the first baffle. The method may further comprise preventing air in a first side of the cabinet below a second baffle from mixing with air in the first side of the cabinet above the second baffle. The method may further comprise preventing air in the first side of the cabinet in front of a third baffle from mixing with air in a rear of the cabinet. The method may further comprise preventing air below the device and in front of a fourth baffle from mixing with air in a rear of the cabinet.

### BRIEF DESCRIPTION OF THE FIGURES

The foregoing and other features of this disclosure will become more fully apparent from the following description and appended claims taken in conjunction with the accompanying drawings. Understanding that these drawings depict only some embodiments in accordance with the disclosure and are therefore not to be considered limiting of its scope, the disclosure will be described with additional specificity and detail by reference to the accompanying drawings in which:

FIG. 1 is a perspective view of an air flow cabinet in accordance with an embodiment of the invention.

FIG. 2 is a perspective view of a door of an air flow cabinet in accordance with an embodiment of the invention.

FIG. 3 is a partially exploded perspective view of an air flow cabinet in accordance with an embodiment of the invention.

### DETAILED DESCRIPTION OF THE PREFERRED EMBODIMENT(S)

In the following detailed description, reference is made to the accompanying drawings which form a part thereof. In the drawings, similar symbols typically identify similar components unless context indicates otherwise. The illustrative embodiments described in the detailed description, drawings and claims are not meant to be limiting. Other embodiments may be utilized and other changes may be made without departing from the spirit or scope of the subject matter presented herein. It will be readily understood that the aspects of the present disclosure as generally described herein and as illustrated in the accompanying figures can be arranged, substituted, combined, separated and/or designed in a wide variety of different configurations all of which are explicitly contemplated herein.

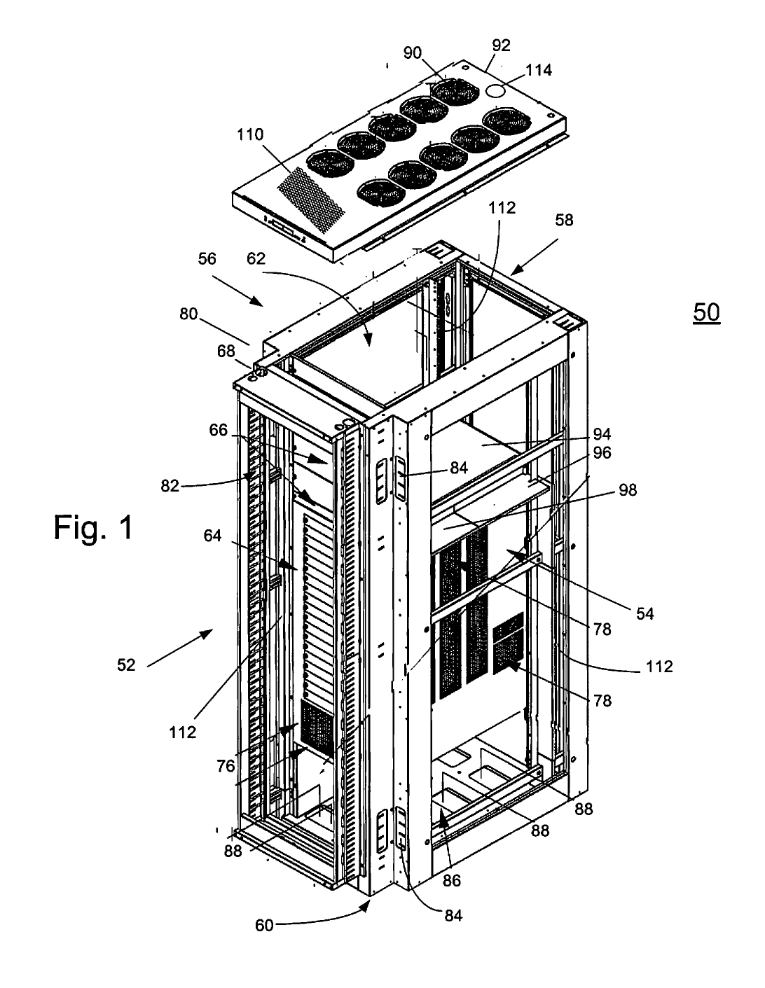

Referring to FIG. 1, there is shown an air flow cabinet 50 in accordance with an embodiment of the invention. Air flow cabinet 50 may include a front 52, a right side 54, a left side 56, a rear 58, a top 62 and a bottom 60 defining a footprint. Right side 54 and left side 56 may be covered with a metal cover. Cabinet 50 may be effective to mount a device 64 inside the cabinet, such as a switch including blank panels 66, on rails 112.

Device 64 may be mounted inside cabinet 50 so that 6 inches of space is available between device 64 and the left side of the footprint of cabinet 50. Device 64 may be mounted so that, for example, 6 inches of space is available between device 64 and a right side of the footprint of cabinet 50. Device 64 may be mounted so that 6 inches of space is available between device 64 and a front of the footprint of cabinet 50. Device 64 may be mounted so that 12 inches of space is available between a rear of device 64 and a rear of the footprint of cabinet 50. Device 64 may be mounted so that 35 inches of space is available between a top of device 64 and a top of cabinet 50. Device 64 may be mounted so that 12 inches of space is available between a bottom of device 64 and a bottom of cabinet 50.

Device 64 may be a switch and may include a first fan 76 and second fans 78. As discussed in more detail below, first fan 76 may be able to suck air from a front of cabinet 50 and blow air toward a rear of cabinet 50 at a rate of, for example, 3000 cfm (cubic feet per minute). Second fans 78 may be able to suck air from right side 54 of cabinet 50 and blow air toward left 56 side of cabinet 50 at a rate of, for example, 3000 cfm. Fans 76, 78 may be used to blow cool air across circuit boards inside device 64.

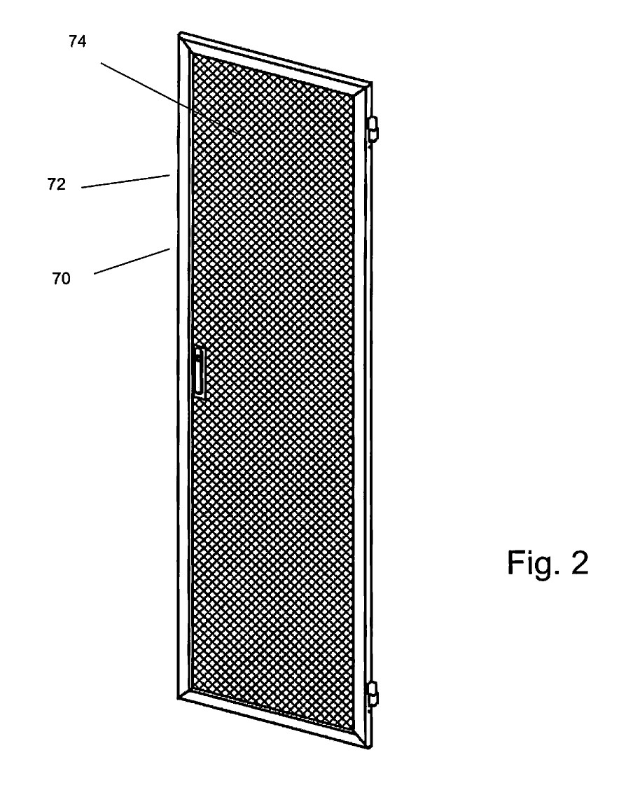

Front 52 may include mounting members 68 which may be used to connect a front door to cabinet 50. Referring also to FIG. 2, a rear door 70 may include a frame 72 holding a perforated panel 74. Panel 74 may be comprised of a mesh type arrangement including a steel material defining openings. In an example, 50% of panel 74 may include the steel material and 50% may be the defined openings.

Focusing again on FIG. 1, front side 52 may include a cable storage area 80 and an opening 84. Cable storage area 80 may be used to manage cables plugged into device 64 such as through the use of tie-downs, spools, etc. A brush 82 may be used to allow cables from cable storage area 80 to pass through and into an inside of cabinet 50 and to device 64. For example, cables may pass through a floor 86 under cabinet 50, pass through storage area 80, opening 84, brush 82 and into device 64. By keeping the cables toward a front of device 64 and pushing heat produced by the switch toward a rear side of cabinet 50, data communication speed through the cables may be maintained. Brush 82 helps keep cold air inside cabinet 50 from mixing with hotter air outside cabinet 50 when cables are inserted inside cabinet 50. Bush 82 may also help prevent the cables from impeding air flow.

Bottom 60 of cabinet 50 includes walls defining plenums 88. Plenums 88 allow air beneath bottom 60 of cabinet 50, and beneath a floor of the room where cabinet 50 is disposed, to be sucked into an inside of cabinet 50 by fans 76, 78. Air below a floor of the room where cabinet 50 is disposed may be even colder than ambient air outside cabinet 50. For example, the air below the floor may be 55 degrees Fahrenheit. Walls defining plenums 88 may be adjusted to control an amount of air flowing through cabinet 50 based on a temperature of an ambient air outside cabinet 50. For example, a temperature probe 114 may be disposed on top 62 of cabinet 50. Based on a temperature reading from probe 114, walls defining plenums 88 may be adjusted to increase or decrease an opening size of plenums 88 and thereby limit a release of air out of top 62.

As mentioned above, fan 78 may blow relatively cool air across circuit boards in device 56. The cool air may originate from under floor 86, travel up to second fans 78, make a first turn and travel from right side 54 of cabinet 50 to left side 56 of cabinet 50. The cool air may then make one more turn and travel upward along left side 56 of cabinet 50 and then exhaust out through top 62. Top 62 may include a perforated panel 110 and/or may include fans 90 of an air flow management module 92. Fans may suck in air at a rate of, for example, 3000 cfm. Similarly, air from plenum 88 may be sucked in by first fan 76, blown out toward a rear of cabinet 50, and then exhaust out through top 62. Rear 58 of cabinet 50 may have a door with an opening, such as a 16″×19″ opening, effective to provide a pressure release for air inside cabinet 50. As fans 76, 78 suck in air from plenums 88 at a high rate, cabinet 50 is effectively sealed from ambient air in that air inside cabinet 50 is prevented from leaving cabinet 50.

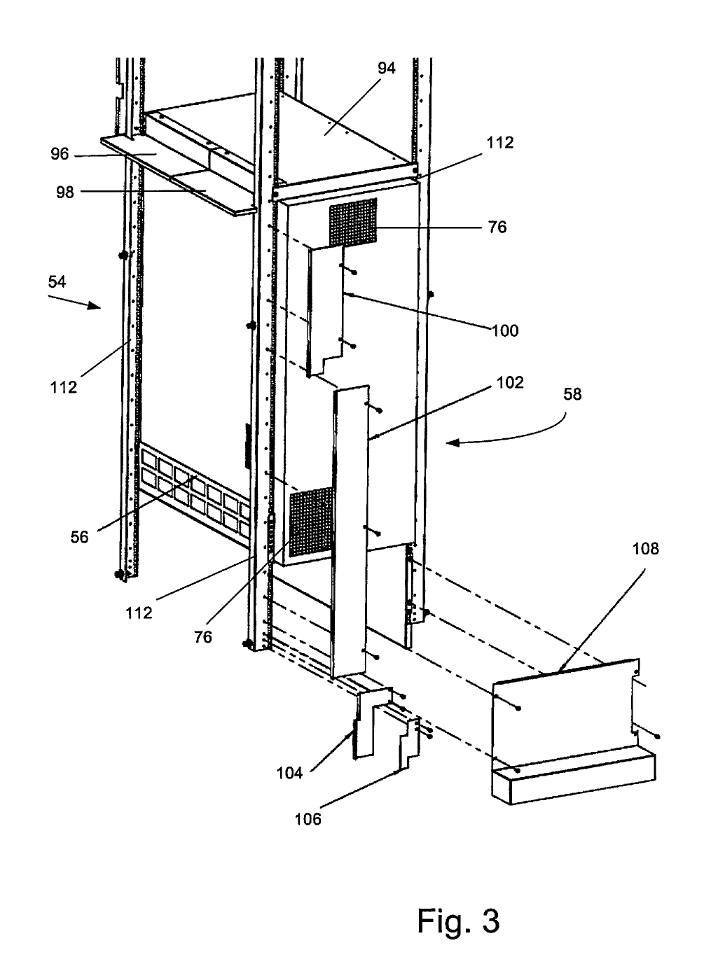

Referring also to FIG. 3, to further reduce temperature inside cabinet 50, cabinet 50 includes baffles defining areas for relatively hot air and areas for relatively cool air and prevents mixing of hot air with cool air. One or more airflow directing baffles 94, 96, 98, 100, 102, 104, 106 and/or 108 may be disposed so as to prevent cool air inside cabinet 50 from mixing with hot air inside cabinet 50. Although multiple baffles are shown, these baffles can be separated or combined into any number of baffles. Baffles generally prevent air from passing through. In some examples, the baffles may be made of metal.

Baffle 94 may be disposed at a location in cabinet 50 so that device 64 may be mounted inside cabinet 50 below baffle 94. Baffle 94 may extend from a rear of device 64 forward toward a front of cabinet 50. Baffle 94 may be effective to prevent air in front 52 of cabinet 50 and below baffle 94 from mixing with air above baffle 94.

Baffles 96, 98 may be disposed at a location in the right side 54 and may extend from baffle 94 toward a right end of the footprint of cabinet 50. Baffles 96, 98 may be disposed in cabinet 50 so as to prevent air in the right side of cabinet 50 and below baffles 96, 98 from mixing with air above baffles 96, 98.

Baffles 100, 102, 104 and/or 106 may be disposed at a location in right side 54. Baffles 100, 102, 104 and/or 106 may be disposed in cabinet 50 so as to prevent air in right side 54 of cabinet 50 and in front of baffles 100, 102, 104 and/or 106 from mixing with air in rear 58 of cabinet 50 behind baffles 100, 102, 104 and/or 106.

Baffle 108 may be disposed in rear 58 of cabinet 50. Baffle 108 may be disposed in cabinet 50 so as to prevent air below device 64 and in a front of baffle 108 from mixing with air in rear 58 of cabinet 50.

Baffles 94, 96, 98, 100, 102, 104 and/or 106 effectively define chambers for relatively cool air and for relatively hot air. Moreover, baffles 94, 96, 98, 100, 102, 104 and/or 106 prevent the relatively cool air from mixing with the relatively hot air. In this way, cool air below floor 86 stays in a front of cabinet 50 and on right side 54 of cabinet 50 below baffle 94. Hot air stays on left side 56, above baffle 94, and in rear 58 of cabinet 50. Cool air coming through plenums 88 is prevented from escaping through a top or rear or cabinet 50. Hot air comes out of device 56 on left side 56 of cabinet 50 and exhausts upward through fans 90.

Among other benefits, a system in accordance with this disclosure may be able to keep modern switches relatively cool even though more heat is produced by these switches and higher rated fans are used than previous switches. These switches may be placed in an enclosure with a small footprint thereby maximizing valuable data center space. As air from below the floor is used, the coldest available air is used to cool a switch inside the cabinet. As the air goes through only a limited number of turns through the switch, less resistance is applied to the air and so less heat gain is experienced and efficiency is increased. Baffles inhibit a mixing between relatively hot air and relatively cool air.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A cabinet effective to mount a device, the cabinet comprising:
a front;
a rear;
a first side;
a second side;
a top;
a bottom;
a first baffle disposed in the cabinet so that the device may be mounted in the cabinet below the first baffle, the first baffle further disposed in the cabinet so as to prevent air in a front of the cabinet below the first baffle from mixing with air above the first baffle;
a second baffle disposed in the first side, the second baffle disposed in the cabinet so as to prevent air in the first side of the cabinet below the second baffle from mixing with air in the first side of the cabinet above the second baffle;
a third baffle disposed in the first side, the third baffle disposed in the cabinet so as to prevent air in the first side of the cabinet in front of the third baffle from mixing with air in a rear of the cabinet; and
a fourth baffle disposed in the rear of the cabinet, the fourth baffle disposed in the cabinet so as to prevent air beneath the device and toward a front of the fourth baffle from mixing with air in a rear of the cabinet.

2. The cabinet as recited in claim 1, wherein the top includes at least one fan.

3. The cabinet as recited in claim 1, wherein the top includes a perforated panel.

4. The cabinet as recited in claim 1, further comprising a cable storage area in the front, the cable storage area effective to manage cables.

5. The cabinet as recited in claim 4, further comprising at least one brush in the front, the brush effective to allow at least one of the cables to pass through.

6. The cabinet as recited in claim 1, wherein the bottom includes walls defining at least one plenum.

7. The cabinet as recited in claim 6, wherein the walls are effective to adjust an opening size of the plenum.

8. The cabinet as recited in claim 1, further comprising a front door, wherein the front door includes a frame holding a perforated panel.

9. A combination of a cabinet and a device, the combination comprising:
a cabinet;
a device mounted in the cabinet; and
the cabinet comprising
a front;
a rear;
a first side;
a second side;
a top;
a bottom;
a first baffle disposed above the device, the first baffle further disposed in the cabinet so as to prevent air in a front of the cabinet below the first baffle from mixing with air above the first baffle;
a second baffle disposed in the first side, the second baffle disposed in the cabinet so as to prevent air in the first side of the cabinet below the second baffle from mixing with air in the first side of the cabinet above the second baffle;
a third baffle disposed in the first side, the third baffle disposed in the cabinet so as to prevent air in the first side of the cabinet in front of the third baffle from mixing with air in a rear of the cabinet; and
a fourth baffle disposed in the rear of the cabinet, the fourth baffle disposed in the cabinet so as to prevent air below the device and in a front of the fourth baffle from mixing with air in a rear of the cabinet.

10. The combination as recited in claim 9, wherein the top includes at least one fan.

11. The combination as recited in claim 9, wherein the top includes a perforated panel.

12. The combination as recited in claim 9, further comprising a cable storage area in the front, the cable storage area effective to manage cables.

13. The combination as recited in claim 12, further comprising at least one brush in the front, the brush effective to allow at least one of the cables to pass through.

14. The combination as recited in claim 9, wherein the bottom includes walls defining at least one plenum.

15. The combination as recited in claim 14, wherein the walls are effective to adjust an opening size of the plenum.

16. The combination as recited in claim 9, further comprising a front door, wherein the front door includes a frame holding a perforated panel.

17. The combination as recited in claim 9, wherein the device is a switch.

18. A method for reducing a temperature in a cabinet, the method comprising:
preventing air in a front of the cabinet below a first baffle from mixing with air above the first baffle;
preventing air in a first side of the cabinet below a second baffle from mixing with air in the first side of the cabinet above the second baffle;
preventing air in the first side of the cabinet in front of a third baffle from mixing with air in a rear of the cabinet; and
preventing air below the device and in front of a fourth baffle from mixing with air in a rear of the cabinet.

19. The method as recited in claim 18, further comprising blowing air above the device through a top of the cabinet with a fan.

20. The method as recited in claim 19, further comprising sucking air beneath a floor of the cabinet into an inside of the cabinet.
